(19) United States
(12) Patent Application Publication
(10) Pub. No.: US 2005/0057258 A1
(43) Pub. Date: Mar. 17, 2005

(54) Hand mounted holiday tester

(76) Inventors: Jerry J. Colahan, Mesa, AZ (US); Thomas R. Glover, Scottsdale, AZ (US)

Correspondence Address: ROBERT A. PARSONS, 340 E. PALM LN, SUITE 260, PHOENIX, AZ, 85004, US

(21) Appl. No.: 10/942,639

(22) Filed: Sep. 16, 2004

Related U.S. Application Data
(60) Provisional application No. 60/503,273, filed on Sep. 16, 2003.

(51) Int. Cl. G01R 31/00

(52) U.S. Cl. 324/501

(57) ABSTRACT

A hand mounted holiday tester includes a control unit with electrical sensing apparatus for detecting a completed circuit between a positive pole and a negative pole of the control unit. The tester further includes a hand receiving mitten, constructed of non-electrically conductive, flexible material with a front surface generally adjacent and parallel to the palm of a hand in the mitten. A flat sponge is fixedly attached to the front surface of the mitten with the front surface of the sponge substantially parallel to the front surface of the mitten. An electrical contact to the sponge includes a loop of wire embedded in the sponge and electrically coupled to one of the positive pole and the negative pole of the control unit.

### CROSS-REFERENCE TO RELATED APPLICATIONS

This application claims the benefit of U.S. Provisional Application No. 60/503,273, filed 16 Sep. 2003.

### FIELD OF THE INVENTION

This invention relates to testing devices for locating holidays in non-conductive coating on conductive substrates.

### BACKGROUND OF THE INVENTION

In order to maintain confidence in non-conductive coatings on conductive surfaces, it is important that the coating provide adequate protection under the conditions for which it was designed. Often, it is vital that the coating be continuous and free from cracks and pinholes (holidays). Test methods are available which can be used to prove the coating is uninterrupted by holidays or other insufficient coating coverage. When to test is determined by the specifications writer. If the coating is thin and applied in a number of coats, it may be necessary to test between each coat. A fault or holiday in the first coat often causes a fault in the subsequent coats. Frequently, the initial fault may be more easily repaired after all of the coats have been applied. However, in other cases, the fault may prove to be more easily repaired after each coat.

Typical procedures used for determining holidays in non-conductive coatings on conductive substrates employ an electrical current flowing through a low resistance path to trigger an alarm, indicating to the operator the presence of a holiday. Holidays are defined as pinholes and voids in non-conductive coatings that allow current to pass therethrough to the metal base material. These discontinuities are such that they may not be visible. Conventional testing devices employ a wet sponge mounted on an insulated handle. With this type of tester, the sponge is saturated with a conductive liquid and is moved over the surface to be tested. The sponge is connected to one pole of a low voltage source, the other pole being connected to the substrate. A circuit is completed through the liquid carried by the sponge, if the liquid makes contact with the substrate via a fault in the coating, then a current will flow. The current is used to operate an alarm circuit.

One problem with the prior art testing devices is that the handle can be unwieldy and difficult to maneuver in tight or limited space areas. Because of this difficulty in maneuvering, complete areas of a surface to be tested can be missed or poorly tested.

It would be highly advantageous, therefore, to remedy the foregoing and other deficiencies inherent in the prior art.

Accordingly, it is an object of the present invention to provide a new and improved hand mounted holiday tester.

It is another object of the present invention to provide a new and improved hand mounted holiday tester that is easy to use and to manufacture.

It is a further object of the present invention to provide a new and improved hand mounted holiday tester with which coated surfaces in difficult to reach locations and having irregularly shapes can be tested.

### SUMMARY OF THE INVENTION

Briefly, to achieve the desired objects of the instant invention in accordance with a preferred embodiment thereof, a hand mounted holiday tester is provided including a control unit with electrical sensing apparatus for detecting a completed circuit between a positive pole and a negative pole of the control unit. The hand mounted holiday tester further includes a hand receiving structure with a front surface generally adjacent and parallel to the palm of a hand received in the hand receiving structure. A flat sponge with a front surface and an electrical contact is coupled to the sponge with the electrical contact electrically coupled to one of the positive pole and the negative pole of the control unit. The sponge is fixedly attached to the front surface of the hand receiving structure so that the front surface of the sponge is substantially parallel to the front surface of the hand receiving structure.

Further, to achieve the desired objects of the instant invention in accordance with a preferred embodiment thereof the invention further contemplates a method of testing a non-conductive coating on a conductive substrate for holidays, including the step of providing a hand mounted holiday tester with a control unit having electrical sensing apparatus for detecting a completed circuit between a positive pole and a negative pole of the control unit, a hand receiving flexible electrically insulated mitten with a front surface generally adjacent and parallel to a palm of a hand received in the hand receiving structure, a flat sponge with a front surface fixedly attached to the front surface of the mitten with the front surface of the sponge substantially parallel to the front surface of the mitten, and an electrical contact including a loop of wire embedded in the sponge, the electrical contact being electrically coupled to the positive pole of the control unit. The method further includes the steps connecting the negative pole of the control unit to the conductive substrate, wetting the sponge with a conductive liquid, and moving the wetted sponge over the surface of the non-conductive coating to be tested so that holidays are filled with the conductive liquid, and observing the control unit for indications of a holiday.

### BRIEF DESCRIPTION OF THE DRAWINGS

Specific objects and advantages of the instant invention will become readily apparent to those skilled in the art from the following detailed description of a preferred embodiment thereof taken in conjunction with the drawings, in which:

FIG. 1 is a front perspective view of a hand mounted holiday tester according to the present invention;

FIG. 2 is a back perspective view of the holiday tester of FIG. 1 as it appears testing a substrate;

FIG. 3 is a side view of the holiday tester as seen in FIG. 2, portions thereof broken away and shown in section;

FIG. 4 is a front plan view of the holiday tester of FIG. 1; and

FIG. 5 is a perspective view of the holiday tester of FIG. 1 in use by an operator.

### DETAILED DESCRIPTION OF THE PREFERRED EMBODIMENT

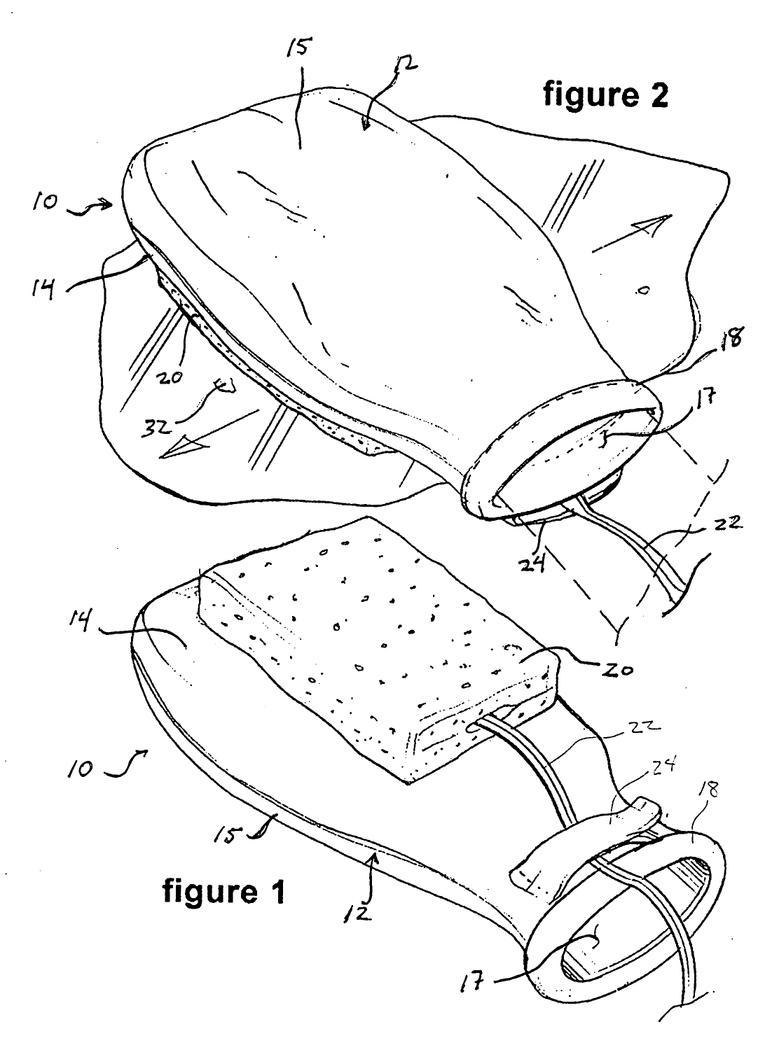

Turning now to the drawings in which like reference characters indicate corresponding elements throughout the several views, attention is first directed to FIG. 1, which illustrates a hand mounted holiday tester, generally designated 10, in accordance with the present invention. Tester 10 includes a hand receiving structure 12, such as a mitten or glove, fabricated of insulating material. The insulating material may be any flexible material, such as rubber, neoprene, or the like, which will prevent an electrical charge from passing into an operator's hand. Hand receiving structure 12 is preferably a mitten as illustrated, and completely encloses the hand of an operator. Hand receiving structure 12 includes a front surface 14 and a back surface 15 defining an interior void for receiving an operator's hand.

In operation or use, a hand is inserted into the interior void through an aperture 17 bounded by a rim 18. The material of hand receiving structure 12 can have an elastomeric characteristic allowing expansion of rim 18 to receive the hand, and retraction thereof to securely engage the hand at the wrist or arm. However, an elastic material or strap with fastener can also be carried at rim 18 to provide a secure engagement about an operator's wrist or arm if a non-elastic material is used. Thus, tester 10 is securely held by an operator.

Tester 10 further includes a sponge 20, as best seen in FIG. 2, coupled to front surface 14 of hand receiving structure 12. Sponge 20 is preferably a cellulose sponge, but can be formed of any material which will absorb and retain a conductive fluid used in the testing process. Referring additionally to FIG. 4, it can be seen that a loop 21 of conductive wire 22 is carried by sponge 20 to provide an electrical circuit used in the test. In the present embodiment, loop 21 is passed centrally through sponge 20. However, it will be understood that wire 22 can be placed in any position where it is in contact with sponge 20. For example, loop 21 can be positioned intermediate sponge 20 and hand receiving structure 12. In another example, wire 22 is coupled to sponge 20 by a coupling member such as an alligator clip. Thus, wire 22 is in contact with and anchored to sponge 20. In other words, wire 22 forms a fixed portion of an electrical circuit having a voltage applied thereto during use and, along with the fluid carried by sponge 20, forms an electrical circuit through holidays.

With additional reference to FIG. 5, it can be seen that, while wire 22 is anchored to sponge 20, it includes a length which extends past rim 18 back to a control unit 30. Control unit 30 is of conventional design, and will not be described in detail, but includes a power source, a detector circuit and a signal device. Additional anchoring of wire 22 is provided by a flap 24 positioned on front surface 14 proximate rim 18. Flap 24 can be opened and closed by use of a fastening device such as snaps or hook and loop fasteners to securely hold wire 22 and prevent loop 21 from being unintentionally withdrawn from sponge 20 due to forces exerted on wire 22.

With reference to FIGS. 2, 3 and 5, hand mounted holiday tester 10 is illustrated in operation testing a non-conductive surface coating 34 on a conductive substrate 35. In operation, tester 10 includes an electrical source of for example 67.5 to 100 V DC that meets various standardized requirements. Wire 22 is coupled to a positive contact electrode of control unit 30 and a negative (ground) terminal of control unit 30 is connected to conductive substrate 35. Sponge 20 is wetted or saturated with sufficient wetting solution to assure moisture penetration of any defect in non-conductive surface coating 34.

There are a number of variables which affect the test results. These include the conducting liquid which is normally tap water, to which has been added some wetting agent and salt. The wetting agent reduces the surface tension, allowing the water to penetrate a fault, and the salt increases conductivity. Moistened sponge 20 is used to test the coated metal by sweeping the moist sponge across the surface thereof, attempting to cover, for example, holiday 32 (See FIG. 2).

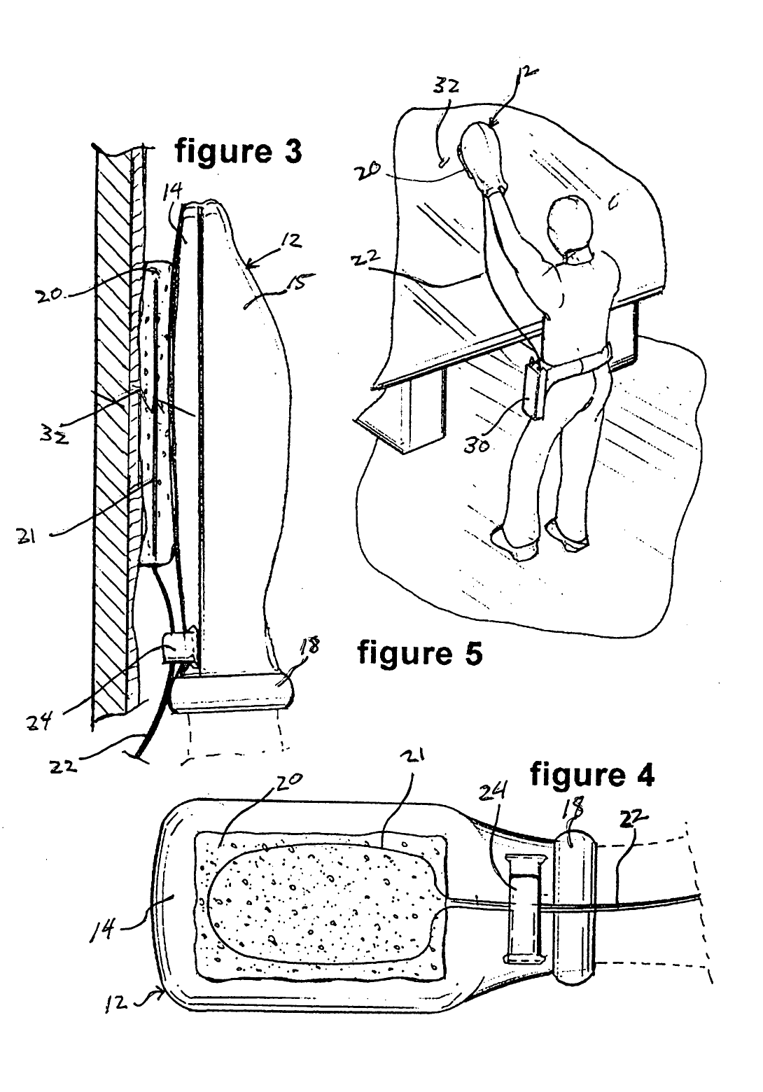

With additional reference to FIG. 3, when sponge 20 passes over holiday 32, conductive fluid from sponge 20 enters the holiday and forms a contact between the uncoated surface of conductive substrate 35 and wire 22. The contact completes a circuit from the positive pole of control unit 30, through wire 22 and loop 21, the liquid in holiday 32, and conductive substrate 35 to the negative pole of control unit 30, causing current to flow, a voltage drop or some other change in electrical characteristics. This change in electrical characteristics is detected by control unit 30 and a signal is generated indicating the presence of a holiday.

By employing hand mounted holiday tester 10 with hand receiving structure 12, coated surfaces in difficult to reach locations and having irregularly shapes, can be tested. Because the hand is used to move the sponge over the surface of a non-conductive coating, close or difficult to cover areas can be more easily reached and tested.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

1. A hand mounted holiday tester comprising:
a control unit including electrical sensing apparatus for detecting a completed circuit between a positive pole and a negative pole of the control unit;
a hand receiving structure including a front surface generally adjacent and parallel to a palm of a hand received in the hand receiving structure;
a flat sponge with a front surface and an electrical contact coupled to the sponge, the electrical contact being electrically coupled to one of the positive pole and the negative pole of the control unit; and
the sponge being fixedly attached to the front surface of the hand receiving structure with the front surface of the sponge substantially parallel to the front surface of the hand receiving structure.

2. A hand mounted holiday tester as claimed in claim 1 wherein the hand receiving structure is in the form of a mitten.

3. A hand mounted tester as claimed in claim 2 wherein the mitten is formed of a flexible insulating material.

4. A hand mounted holiday tester as claimed in claim 3 wherein the flexible insulating material includes one of rubber and neoprene.

5. A hand mounted holiday tester as claimed in claim 2 wherein the mitten is formed with an elastomeric characteristic.

6. A hand mounted holiday tester as claimed in claim 5 wherein the elastomeric characteristic includes a wrist band for holding the mitten firmly on an operator's hand.

7. A hand mounted holiday tester as claimed in claim 1 wherein the electrical contact coupled to the sponge includes a loop of wire.

8. A hand mounted holiday tester as claimed in claim 7 wherein the loop of wire is imbedded in the sponge.

9. A hand mounted holiday tester as claimed in claim 8 wherein the control unit is constructed to be belt mounted on an operator and an extension of the loop of wire is connected to the positive pole of the control unit.

10. A hand mounted holiday tester comprising:
a control unit including electrical sensing apparatus for detecting a completed circuit between a positive pole and a negative pole of the control unit;
a hand receiving mitten including a front surface generally adjacent and parallel to a palm of a hand received in the hand receiving structure, the mitten being constructed of non-electrically conductive material;
a flat sponge with a front surface fixedly attached to the front surface of the mitten with the front surface of the sponge substantially parallel to the front surface of the mitten; and
an electrical contact including a loop of wire embedded in the sponge, the electrical contact being electrically coupled to one of the positive pole and the negative pole of the control unit.

11. A hand mounted tester as claimed in claim 10 wherein the mitten is formed of a flexible insulating material.

12. A hand mounted holiday tester as claimed in claim 11 wherein the flexible insulating material includes one of rubber and neoprene.

13. A hand mounted holiday tester as claimed in claim 10 wherein the control unit is constructed to be belt mounted on an operator and an extension of the loop of wire is connected to the positive pole of the control unit.

14. A hand mounted holiday tester as claimed in claim 10 wherein the mitten is formed with an elastomeric characteristic.

15. A hand mounted holiday tester as claimed in claim 14 wherein the elastomeric characteristic includes a wrist band for holding the mitten firmly on an operator's hand.

16. A method of testing a non-conductive coating on a conductive substrate for holidays, comprising the steps of:
providing a hand mounted holiday tester including a control unit with electrical sensing apparatus for detecting a completed circuit between a positive pole and a negative pole of the control unit, a hand receiving flexible electrically insulated mitten with a front surface generally adjacent and parallel to a palm of a hand received in the hand receiving structure, a flat sponge with a front surface fixedly attached to the front surface of the mitten with the front surface of the sponge substantially parallel to the front surface of the mitten, and an electrical contact including a loop of wire embedded in the sponge, the electrical contact being electrically coupled to the positive pole of the control unit;
connecting the negative pole of the control unit to the conductive substrate;
wetting the sponge with a conductive liquid; and
moving the wetted sponge over the surface of the non-conductive coating to be tested so that holidays are filled with the conductive liquid, and observing the control unit for indications of a holiday.

17. A method as claimed in claim 16 wherein the step of wetting includes providing a solution of water, a wetting agent, and salt and saturating the sponge in the solution.

18. A method as claimed in claim 16 wherein the indications of a holiday provided by the control unit include a change in current, voltage or other electrical characteristic.
